(19) United States
(12) Patent Application Publication
(10) Pub. No.: US 2015/0085205 A1
(43) Pub. Date: Mar. 26, 2015

(54) TOUCH PANEL

(71) Applicants: Kuo-Hsing Chen, New Taipei City (TW); Chung-Hsien Li, Taichung City (TW); Cheng-Yen Yeh, Taichung City (TW); Yu-Ting Chen, Taoyuan County (TW); Chen-Hao Su, Taichung City (TW); Siang-Lin Huang, Taichung City (TW)

(72) Inventors: Kuo-Hsing Chen, New Taipei City (TW); Chung-Hsien Li, Taichung City (TW); Cheng-Yen Yeh, Taichung City (TW); Yu-Ting Chen, Taoyuan County (TW); Chen-Hao Su, Taichung City (TW); Siang-Lin Huang, Taichung City (TW)

(73) Assignee: WINTEK CORPORATION, Taichung City (TW)

(21) Appl. No.: 14/493,366

(22) Filed: Sep. 23, 2014

(30) Foreign Application Priority Data
Sep. 23, 2013 (TW) 102134087

(51) Int. Cl. G06F 3/041; H03K 17/96; G06F 1/16

(52) U.S. Cl. CPC G06F 3/0418; G06F 1/1643; H03K 17/962
USPC 349/12; 200/600

(57) ABSTRACT

A touch panel includes a substrate, a plurality of first conductive elements, and a plurality of second conductive elements. Each of the first conductive elements includes a plurality of first conductive patterns and a plurality of first connection portions alternately connected with each other. The first conductive elements and the second conductive elements are intersected with each other and electrically insulated. Each of the second conductive elements includes a plurality of intersection portions respectively intersected with the first connection portions of each of the first conductive elements. A linewidth of the intersection portions is W1, and 100 μm<W1≦300 μm.

### CROSS-REFERENCE TO RELATED APPLICATION

This application claims the priority benefit of Taiwan application serial no. 102134087, filed on Sep. 23, 2013. The entirety of the above-mentioned patent application is hereby incorporated by reference herein and made a part of this specification.

### BACKGROUND OF THE INVENTION

1. Field of the Invention

The invention relates to a touch panel, and more particularly, to a projected capacitive touch panel.

2. Description of Related Art

In a conventional capacitive touch panel, one of a 2D touch sensor is composed of a plurality of first conductive elements and a plurality of second conductive elements disposed on a substrate, in which the first and second conductive elements are respectively extended along different directions, insulated and intersected with each other. Generally, a common operating method for touch control is to perform input by using an electrical conductor such as a finger or a capacitive stylus. In consideration of requirements for a more accurate input, a contact area of the stylus is usually designed to be smaller. Accordingly, when it comes to improve touch resolution and sensing linearity, the first conductive elements and the second conductive elements are usually designed into more complex patterns.

In order to meet requirements for improving touch sensitivity, a pattern of the regions where the first conductive elements and the second conductive elements are not overlapped is usually densely distributed. Meanwhile, in order to prevent sensing sensitivity from being influenced by a parasitic capacitance generated at the regions where the first conductive elements and the second conductive elements are overlapped, the intersections of the first conductive elements and the second conductive elements are usually designed into an narrow elongated pattern. However, such design of the narrow elongated pattern is prone to a current crowding effect thereby causing signal attenuation or triggering an electrostatic discharge effect. Further, in consideration of thinning the touch panel, a small area of insulation structures may be disposed to separate the intersections of the first conductive elements and the second conductive elements, so that the first conductive elements and the second conductive elements are electrically independent from each other. Generally, the insulation structure is a relatively protruded structure, namely, the insulation structure may cause an uneven surface, thereby increasing difficulties in subsequent steps for layer disposition and film patterning. More specifically, under said structure, during manufacturing processes of the first conductive elements and the second conductive elements, conductive material located above the insulation patterns are prone to cracks, or the conductive material at a climbing portion of the insulation structures may have thinner film thickness, thereby influencing a quality of the touch panel. Furthermore, the electrostatic discharge effect may cause breakages of the conductive material, such that local area of the capacitive touch panel may unable to provide touch-sensing function.

### SUMMARY OF THE INVENTION

Accordingly, the invention is directed to a touch panel in which a capability of resisting a static discharge effect can be improved while ensuring a quality of a sensing sensitivity by controlling a linewidth of the conductive elements.

A touch panel of the invention includes a substrate, a plurality of first conductive elements and a plurality of second conductive elements. The first conductive elements are disposed on the substrate; each of the first conductive elements includes a plurality of first conductive patterns and a plurality of first connection portions; each of the first connection portions is disposed between adjacent two of the first conductive patterns; and each of the first conductive patterns is electrically connected to one of the first connection portions. The second conductive elements are electrically insulated from the first conductive element. Each of the second conductive elements includes a plurality of intersection portions respectively intersected with the first connection portions. A linewidth of the intersection portions is represented as W1, in which it satisfies a condition of 100 μm<W1≦300 μm. A sum of areas of regions where the first conductive elements and the second conductive elements are not overlapped is greater than a sum of areas of regions where the first conductive elements and the second conductive elements are overlapped.

In an embodiment, the touch panel further includes a plurality of insulation patterns, and each of the insulation patterns is disposed between one of the first connection portions and a corresponding one of the intersection portions intersected with the one of the first connection portions.

In an embodiment, each of the second conductive elements includes a plurality of second conductive patterns and at least one second connection portion, each of the at least one second connection portion is disposed between adjacent two of the second conductive patterns, each of the second conductive patterns is electrically connected to one of the at least one second connection portion, and the intersection portions are located in the second conductive patterns.

In an embodiment, a linewidth of the second connection portion is W2, and satisfies a condition of 20 μm<W2<W1.

In an embodiment, an accommodating space is defined between adjacent two of the second conductive patterns and any one of two sides of the second connection portion, and each of the first conductive elements has at least one first conductive branch being extended into the accommodating space.

In an embodiment, the insulation pattern exposes two ends of the first connection portion, the first conductive patterns are disposed on the two ends of the first connection portion, a partial region of the insulation pattern and the substrate, the first conductive pattern being inwardly extended from an edge of the insulation pattern for a distance not less than 20 μm.

In an embodiment, a minimum linewidth of the first connection portion is not greater than the linewidth of the intersection portion.

In an embodiment, the first connection portions include a plurality of first connection patterns and a plurality of second connection patterns, and the first connection patterns and the second connection patterns are alternately disposed between adjacent two of the first conductive patterns, wherein two or more of the first connection patterns are disposed between adjacent two of part of the first conductive patterns, and each two of the first connection patterns encircle an opening.

In an embodiment, a width of the second connection pattern is greater than a width of the first connection pattern.

In an embodiment, a part of the second conductive element is surrounded by a normal projection of two of the first connection patterns being arc-shaped.

In an embodiment, the first connection pattern is surrounded by a normal projection of two of the intersection portions being arc-shaped.

In an embodiment, a maximum width of the second connection pattern is greater than a minimum width of the first conductive pattern.

In an embodiment, the second conductive element includes a hollow portion, the intersection portions are located at two ends of the hollow portion, the first connection portion includes a filling section and a plurality of first intersecting sections, the filling section is located in the hollow portion, the first intersecting sections are located at the two ends of the filling section, and each of the first intersecting sections is intersected with one of the intersection portions and electrically connects the filling section and one of the first conductive patterns together.

In an embodiment, each of the second conductive elements includes a conductive trunk, and the intersection portions are located in the conductive trunk, wherein a linewidth of any portion of the conductive trunk other than the intersection portions is substantially identical to a linewidth of any one of the intersection portions.

In an embodiment, each of the second conductive elements further includes a plurality of second conductive branches, and the second conductive branches are extruded from two opposite sides of the conductive trunk.

In an embodiment, a linewidth W3 of each of the second branches is substantially uniform, and is not greater than the linewidth W1.

In an embodiment, a plurality of floating dummy electrodes is further respectively located between the conductive trunk and the first conductive pattern, wherein each of the floating dummy electrodes has at least one terminal with acute angle.

In an embodiment, a plurality of floating dummy electrodes is further included, wherein two or more of the floating dummy electrodes are located an insulating spacing between one of the conductive trunks and the adjacent one of the first conductive patterns.

Based on a purpose of the invention, a touch panel having a light transmissive region is further provided. The touch panel includes a substrate made of light transmissive materials, a plurality of first conductive elements, a plurality of second conductive elements and a plurality insulation patterns. The first conductive elements are disposed on the substrate and at least located at the light transmissive region; each of the first conductive elements includes a plurality of first conductive patterns and a plurality of first connection portions; each of the first connection portions is disposed between adjacent two of the first conductive patterns; and each of the first conductive patterns and one of the first connection portions are electrically connected to each other. The second conductive elements are disposed on the substrate and at least located at the light transmissive region, and the first conductive elements and the second conductive elements are intersected with each other and electrically insulated. The second conductive element includes a plurality of intersection portions respectively intersected with the first connection portions of each of the first conductive elements. A linewidth of the intersection portion is greater than a linewidth of the first connection portion. Each of the insulation patterns is disposed between one of the first connection portions and a corresponding one of the intersection portions intersected with the one of the first connection portions. A sum of areas of regions where the first conductive elements and the second conductive elements are not overlapped is greater than a sum of areas of regions where the first conductive elements and the second conductive elements are overlapped.

In an embodiment, a linewidth of the intersection portion is W1, and satisfies a condition of 100 μm<W1≦300 μm.

In an embodiment, each of the second conductive elements includes a conductive trunk, and the intersection portions are located in the conductive trunk. A linewidth of any portion of the conductive trunk other than the intersection portions is substantially identical to the linewidth of any one of the intersection portions.

In an embodiment, the touch panel further includes a decoration layer and a plurality of signal transmission lines, in which the decoration layer is disposed on the substrate and corresponding to a light shielding region adjoined to the light transmissive region. The signal transmission lines are concealed by the decoration layer. The first conductive elements and the second conductive elements are further located at the light shielding region to electrically connect to the signal transmission lines on the decoration layer.

Based on above, in the touch panel of the invention, the linewidths of the intersections of the first conductive elements and the second conductive elements are well controlled, and the sum of areas of regions where the first conductive elements and the second conductive elements are not overlapped is greater than a sum of areas of regions where the first conductive elements and the second conductive elements are overlapped, such that a preferable touch sensitivity can be provided. Further, in order to provide a thinner and lighter touch panel, the first conductive elements and the second conductive elements are insulated from each other in each of the overlapping regions by disposing discontinuous insulation patterns. Furthermore, the touch panel can be even thinner and lighter when the first conductive elements, the second conductive elements, the insulation patterns and the decoration layer are formed on a cover lens. In this case, since the second conductive element located on the insulation pattern has a sufficient width, the capability of resisting a static discharge effect is provided to avoid the cracks occurring on the second conductive elements and ensure that the touch panel may provide a favorable performance. Moreover, by making the second conductive elements to have a uniform linewidth, the current crowding effect may be reduced to provide a simpler arrangement leading to an easier production.

To make the above features and advantages of the disclosure more comprehensible, several embodiments accompanied with drawings are described in detail as follows.

### BRIEF DESCRIPTION OF THE DRAWINGS

FIG. 1A is a schematic top view of a touch panel according to an embodiment of the invention.

FIG. 1B is a schematic cross-sectional view taken along line A-A′ depicted in FIG. 1A.

FIG. 1C is a schematic cross-sectional view taken along line B-B′ depicted in FIG. 1A.

FIG. 2A is a schematic top view of a touch panel according to another embodiment of the invention.

FIG. 2B is a schematic cross-sectional view taken along line C-C′ depicted in FIG. 2A.

FIG. 3A is a schematic top view of a touch panel according to another embodiment of the invention.

FIG. 3B is a schematic cross-sectional view taken along line D-D′ depicted in FIG. 3A.

FIG. 4A is a schematic top view of a touch panel according to another embodiment of the invention.

FIG. 4B is an enlarged schematic view of an area M depicted in FIG. 4A.

FIG. 4C is a schematic cross-sectional view taken along line E-E′ depicted in FIG. 4A.

FIG. 5A is a schematic top view of a touch panel according to another embodiment of the invention.

FIG. 5B is a schematic cross-sectional view taken along line F-F′ depicted in FIG. 5A.

FIG. 5C is an enlarged schematic view of a driving circuit depicted in FIG. 5A.

FIG. 6 is a schematic top view of a touch panel according to another embodiment of the invention.

FIG. 7 is a schematic top view of a touch panel according to another embodiment of the invention.

FIG. 8 is a schematic top view of a touch panel according to another embodiment of the invention.

### DESCRIPTION OF THE EMBODIMENTS

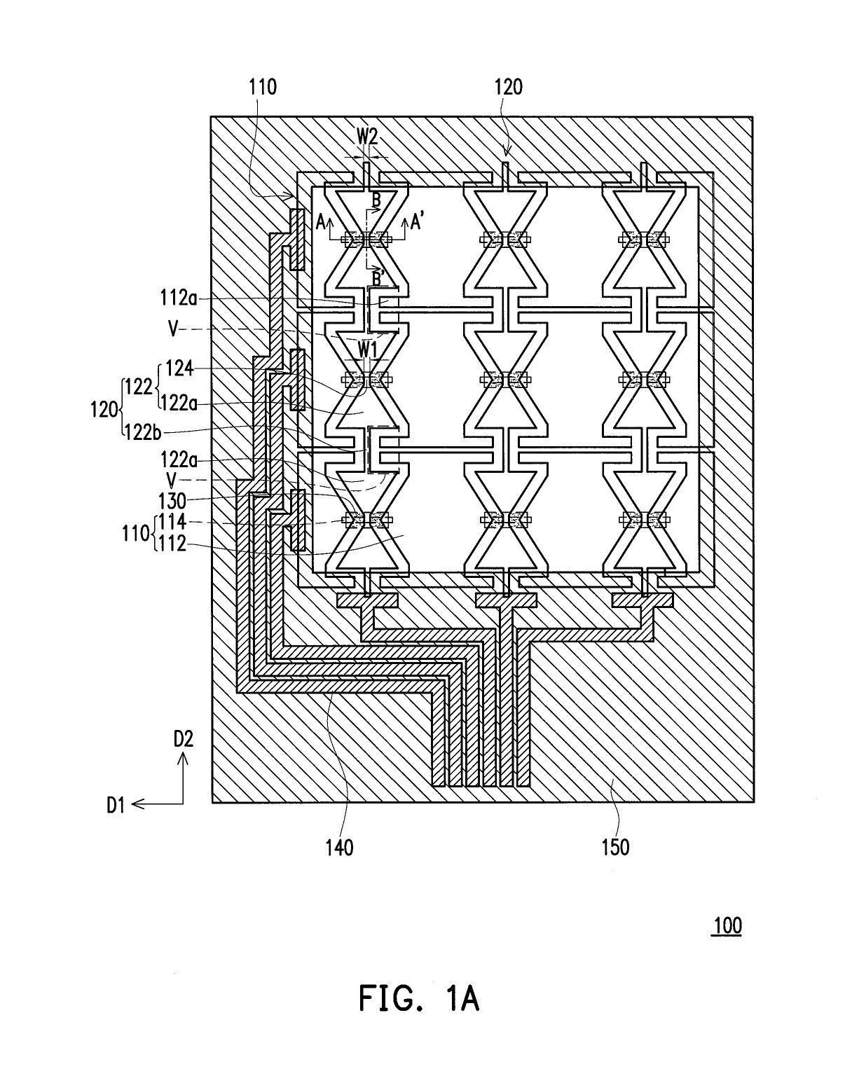

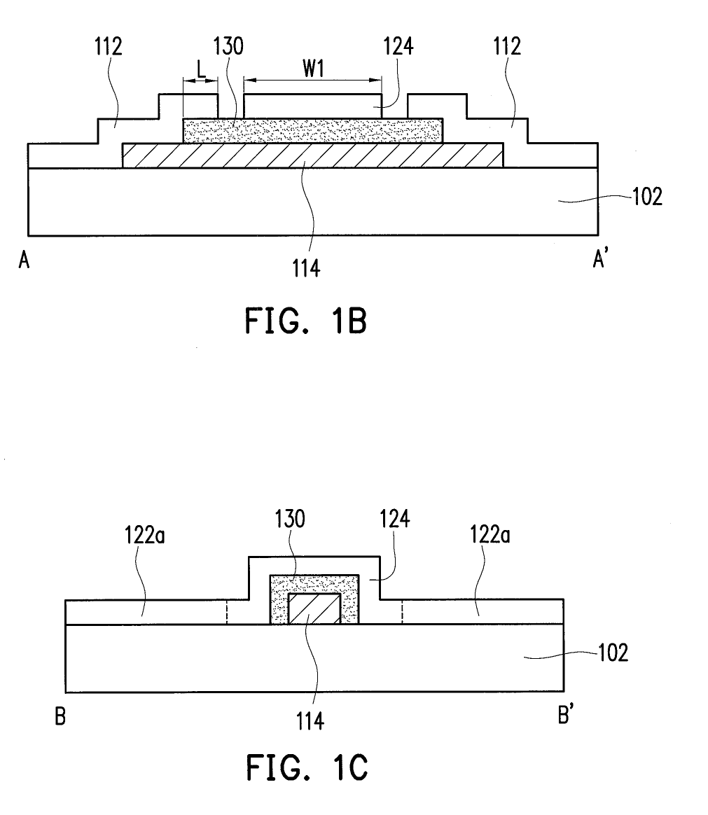

FIG. 1A is a schematic top view of a touch panel according to an embodiment of the invention. FIG. 1B is a schematic cross-sectional view taken along line A-A′ depicted in FIG. 1A. FIG. 1C is a schematic cross-sectional view taken along line B-B′ depicted in FIG. 1A. Referring to FIG. 1A, FIG. 1B and FIG. 1C, a touch panel 100 includes a substrate 102, a plurality of first conductive elements 110, a plurality of second conductive elements 120, a plurality of insulation patterns 130, a plurality of signal transmission lines 140 and a decoration layer 150. The touch panel 100 may include a light transmissive region and a light shielding region for being positioned on or integrated with a display. The light transmissive region corresponds to display units such as a liquid crystal display or an organic light-emitting diode, and the light shielding region is configured to shade visible elements or light not intended to be seen, such element may be, for example, the signal transmission lines 140 made of visible conductive material. In order to maximize a display area of an electronic device, demands for narrower border are increased, the visible elements are usually positioned in a peripheral region of the substrate 102. Moreover, the visible elements may be positioned corresponding to only one side margin of the substrate 102. Based on the same reason, at least one side margin of the touch panel 100 may have the light shielding region, while the remaining part of the touch panel 100 may correspond to the light transmissive region. The decoration layer 150 is positioned within the light shielding region, so as to be disposed on at least one side margin of the substrate 102. The decoration layer 150 is composed of a light shielding material, which is defined as a material deemed to render a light lost when the light passes through an interface thereof, up to and including complete opacity. Through the decoration layer 150, the visible elements or light not intended to be seen in the device can be concealed. A material of the decoration layer 150 may be a ceramic, a diamond-like carbon, an ink or a light shielding photoresist, but the invention is not limited thereto. Furthermore, in other embodiments not illustrated, the light shielding region may also include a visible icon, such as texts, logos, decorative patterns or function keys. Or, a part of the decoration layer may be patterned to be a light transmissive pattern.

Each of the first conductive elements 110 is disposed on the substrate 102 and extends along a first direction D1. The first conductive element 110 includes a plurality of first conductive patterns 112 and a plurality of first connection portions 114. Each of the first connection portions 114 is disposed between and electrically connected to adjacent two of the first conductive patterns 112. The first conductive pattern 112 may be made of a transparent conductive material including indium tin oxide (ITO), indium-zinc oxide (IZO), gallium-zinc oxide (GZO), carbon nanotube-based thin films, metal nanowires, such as silver nanowires, graphene, silicene or other high conductive materials with invisible configuration, such as metal grids composed of metal wires with a linewidth less than 10 μm, but the invention is not limited thereto.

Each of the second conductive elements 120 is disposed on the substrate 102 and extends along a second direction D2 intersected with the first direction D1. The second conductive elements 120 are electrically insulated from the first conductive elements 110. A sum of areas of regions where the first conductive elements 110 and the second conductive elements 120 are not overlapped is greater than a sum of areas of regions where the first conductive elements 110 and the second conductive elements 120 are overlapped. Accordingly, the conductive elements may be more densely distributed to improve a sensing sensitivity and a coordinate resolution of the touch panel. Therein, the second conductive element 120 includes a plurality of intersection portions 124 respectively intersected with the first connection portions 114 of each of the first conductive elements 110. A minimum linewidth of the first intersection portion 114 may be not greater than a linewidth W1 of the intersection portion 124. In the present embodiment, the second conductive element 120 includes a plurality of second conductive patterns 122 and a plurality of second connection portions 122b. Each of the second connection portions 122b is disposed between and electrically connected to adjacent two of the second conductive patterns 122. The second conductive pattern 122 may be composed of materials such as a transparent conductive material including indium tin oxide (ITO), indium-zinc oxide (IZO), gallium-zinc oxide (GZO), carbon nanotube-based thin films, metal nanowires, such as silver nanowires, graphene, silicene or other high conductive materials, with invisible configuration, such as metal grids composed of metal wires with a linewidth less than 10 μm, but the invention is not limited thereto. Therein, the second connection portion 122b may be of a thin metal wire or a material identical to that of the second conductive patterns 122.

Each of the insulation patterns 130 is disposed between the first connection portion 114 and the intersection portion 124 of the second conductive element 120, so that the first conductive element 110 and the second conductive element 120 are electrically insulated from each other. In the present embodiment, each of the insulation patterns 130 covers the first connection portion 114 of the first conductive element 110. By using the first conductive element 110 and the second conductive element 120, in case a conductive object (e.g., a finger) is approaching or contacting a surface of the touch panel, coupling capacitances are then generated between the object and the approaching conductive elements. As a result, a position or a movement of the object may be detected according to capacitance variation at a region where the object is approached to or contacted. Therein, the object may contact an outer surface of an insulator such as a cover lens, to perform a touch control. Or, a proximity hovering touch control without touching the touch panel may be performed. In addition, details related to a touch detection measurement method of the capacitive touch panel may refer to the well known measurement methods, such as a self capacitance measurement method or a mutual capacitance measurement method. However, the invention is not limited to any specific measurement methods.

The insulation patterns 130 are not overlapped with the second connection portions 122b. More specifically, the first connection portion 114 is, for example, a strip conductive pattern disposed on the substrate 102, and made of a conductive material including a metal material, a metallic oxide material, or a composite laminate including at least one metal layer and at least one metallic oxide layer, but the invention is not limited thereto. In case the touch panel 100 is disposed in front of a display, the first connection portion 114 may be made of the conductive material selected from the above-mentioned transparent conductive material or the thin metal wire that is hardly visible to naked-eye, in which a linewidth of the thin metal wire is usually less than 20 μm. The insulation pattern 130 covers a partial region of the first connection portion 114 and expose two ends of the first connection portion 114. Herein, the first conductive patterns 112 disposed next to the first connection portion 114 respectively covers the two ends of the first connection portion 114 exposed by the insulation pattern 130, so that the first conductive patterns 112 along the first direction D1 are electrically connected together by the first connection portion 114 in one first conductive element 110. In the present embodiment, the first connection portion 114 and the first conductive pattern 122 are fabricated separately, and the first conductive pattern 112 is further extended to cover a partial region of the insulation pattern 130. More specifically, the first conductive pattern 122 may be inwardly extended from an edge of the insulation pattern 130 for a distance L≧20 μm. Accordingly, it is ensured that the first connection portion 114 is not damaged by an etchant for patterning the first conductive pattern 112 in a subsequent process, namely, the electrical connection between the first connection portion 114 and the first conductive pattern 112 in one first conductive element 110 is ensured.

In the present embodiment, the first direction D1 and the second direction D2 are intersected and, for example, perpendicular to each other. Each of the intersection portions 124 of the second conductive element 120 is located in each of the second conductive pattern 122, and it covers the insulation pattern 130. Herein, the intersection portion 124 on the insulation pattern 130 is, for example, of a strip having a linewidth W1 satisfying a condition of 100 μm<W1≦300 μm. Since the intersection portion 124 has a sufficient width, the intersection portion 124 may not be completed fractured even if the electrostatic discharge effect occurs on the intersection portion 124 located on the insulation pattern 130. In other words, the second conductive element 120 of the touch panel 100 may be ensured to maintain its normal performance. In addition, the invention restricts the intersection portion 124 to fall within a range less than or equal to 300 μm, such that influences to the sensing sensitivity of the touch panel due to the parasitic capacitance on the regions where the first conductive elements 110 and the second conductive elements 120 are overlapped being overly great may be prevented.

Furthermore, in order to improve a resolution of the touch panel 100, patterns of the first conductive elements 110 and the second conductive elements 120 may be more complicated. More specific, the second conductive pattern 122 includes two primary conductive patterns 122a and the intersection portion 124 located between the two primary conductive patterns 122a. The intersection portion 124 may be made of the thin metal wire or a material identical to that of the primary conductive pattern 122a. An accommodating space V is defined between adjacent two of the second conductive patterns 122 and any one of two sides of the second connection portion 122b. The first conductive pattern 112 may further include a plurality of first conductive branches 112a each extended into one of the accommodating spaces V. Therein, a linewidth of the second connection portion 122b is represented as W2, in which it satisfies a condition of 20 μm<W2<W1. Accordingly, the capacitance variation provided from the accommodating space V once a finger is laid on is reduced, so as to prevent accuracy of detection of touch from being influenced. Therein, the linewidth of the second connection portion 122b is not particularly limited, as long as the linewidth falls within a load range of a control circuit to provide an electrical connection function.

In the present embodiment, the substrate 102 is a supporting material and provides a surface on which the first conductive elements 110, the second conductive elements 120, the insulation patterns 130, the signal transmission line 140 and the decoration layer 150 are formed. A part of the first conductive elements 110 or a part of the second conductive elements 120 are extended from the light transmissive region onto the decoration layer 150 to be further away from the substrate 102, and electrically connected to the signal transmission lines 140 on the decoration layer 150. The substrate 102 may serve to cover and protect elements at lower portion below, and a side of the substrate 102 where the conductive elements are not disposed can provide an operating interface for users, which includes the surface of the substrate 102 opposite to the surface having the conductive elements formed thereon. That is, in the present embodiment, the substrate 102 may be the cover lens made of a tempered glass or other rigid light transmissive materials. Accordingly, the touch panel 100 may be thinner and lighter. Furthermore, functional layers such as an anti-glare film or an anti-reflection film may be disposed on the surface of the substrate 102 where the conductive elements are not disposed, so that the surface of the outermost functional layer serves as the operating interface for users. Nevertheless, in some embodiments, the substrate 102 may be a color filter substrate, a thin film substrate, an upper cover plate of a display panel or a lower substrate of a display panel. In this case, the first conductive elements 110 and the second conductive elements 120 can be further covered and protected by an anti-scratch protection layer or an additional cover lens. The decoration layer 150 may not be formed on the substrate 102, for example, it is preferably formed on an inner surface of the additional cover lens rather than the substrate 102. A surface of the anti-scratch protection layer or the additional cover lens where the conductive elements are not disposed can serve as the operating interface for users.

It should be noted that the reference numerals and a part of the contents in the previous embodiment are used in the following embodiments, in which identical reference numerals indicate identical or similar components, and repeated description of the same technical contents is omitted. For a detailed description of the omitted parts, reference can be found in the previous embodiment, and no repeated description is contained in the following embodiments.

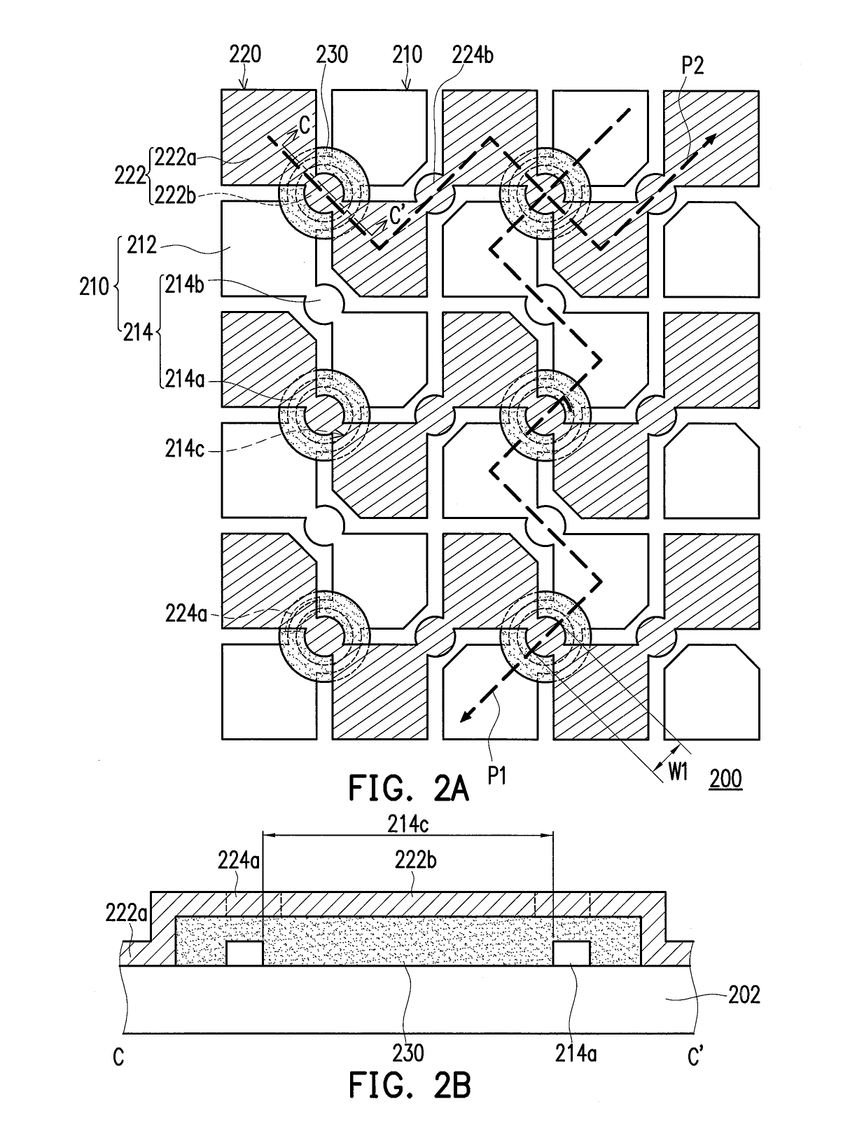

FIG. 2A is a schematic top view of a touch panel according to another embodiment of the invention. FIG. 2B is a schematic cross-sectional view taken along line C-C′ depicted in FIG. 2A. Referring to FIG. 2A and FIG. 2B together, a touch panel 200 includes a plurality of first conductive elements 210 and a plurality of second conductive elements 220 disposed on a substrate 202. Herein, the signal transmission line is omitted in illustration, and the decoration layer may be selectively formed on the substrate 202. The first conductive elements 210 and the second conductive elements 220 are intersected with each other. The first conductive element 210 includes a plurality of first conductive patterns 212 and a plurality of first connection portions 214, which are electrically connected to each other. The first connection portion 214 is disposed between adjacent two of the first conductive patterns 212. The first connection portions 214 in each first conductive element 210 include first connection patterns 214a and second connection patterns 214b alternately disposed between adjacent ones of the first conductive patterns 212. Therein, part of adjacent ones of the first conductive patterns 212 connected together by two or more of the first connection patterns 214a disposed therebetween, in which two of the first connection patterns 214a encircle an opening 214c. Above-said disposition has an improved compressive strength and may be more preferably in preventing an open circuit due to breakage of the first connection pattern 214a caused by a surge, as in comparison with a disposition using only single one first connection pattern 214a to connect the adjacent ones of the first conductive patterns 212. In the present embodiment, two arc-shaped first connection patterns 214a are disposed between adjacent ones of the first conductive patterns 212, in which a circular opening 214c is encircled by adjacent ones of the first connection patterns 214a and first conductive patterns 212. Each insulation pattern 230 covers on the arc-shaped first connection pattern 214a and a part of the first conductive pattern 212; while the second connection pattern 214b is not covered by the insulation pattern 230. Therein, the second connection pattern 214b having a circular profile is capable of reducing overall conduction impedance of the first conductive elements 210. In the present embodiment, the first conductive patterns 212 may be derived from a rhombus, but the invention is not limited thereto. The first conductive patterns 212 and the first connection portions 214 in each first conductive element 210 are, for example, extended and arranged along a first path P1, and the first path P1 is zigzag.

The second conductive element 220 includes a plurality of second conductive patterns 222 and a plurality of second connection portions 224b, and adjacent two of the second conductive patterns 222 can be electrically connected through one of the second connection portions 224b. Each of the second conductive patterns 222 has two primary conductive patterns 222a and a secondary conductive pattern 222b. Therein, the secondary conductive pattern 222b is disposed between the two primary conductive patterns 222a, and an area of the secondary conductive pattern 222b is less than an area of the primary conductive pattern 222a. An intersection portion 224a is located in the primary conductive pattern 222a. In the present embodiment, the second connection portion 224b may have, for example, a circular profile configured to reduced overall conduction impedance of the second conductive elements 220. The primary conductive pattern 222a may be, for example, derived from a rhombus. The secondary conductive pattern 222b may have, for example, a circular profile, but the invention is not limited thereto. The second conductive patterns 222 and the second connection portions 224b in each second conductive element 220 are, for example, extended and arranged along a second path P2, and the second path P2 is zigzag. The second path P2 is intersected with the first path P1.

The touch panel 200 further includes a plurality of insulation patterns 230. The insulation patterns 230 are at least disposed at intersections of the first conductive elements 210 and the second conductive elements 220, so that the first conductive elements 210 are electrically insulated from the second conductive elements 220. In the present embodiment, each insulation pattern 230 covers the first connection pattern 214a and a part of the first conductive pattern 212, and the intersection portion 224a of the second conductive element 220 and a part of the secondary conductive pattern 222b are disposed on the insulation pattern 230. However, in some embodiments, the insulation pattern 230 may be a ring structure only for separating the intersection portion 224a from the first connection pattern 214a, and it is possible not to dispose the secondary conductive pattern 222b on the insulation pattern 230. In addition, the second connection portion 224b is not disposed on the insulation pattern 230 but is coplanar to the primary conductive pattern 222a instead.

As shown in FIG. 2A, the arc-shaped first connection patterns 214a surround the circular secondary conductive pattern 222b. Therefore, additional amount of fringing capacitance may be provided between the first connection pattern 214a and the secondary conductive pattern 222b, so as to improve mutual induction sensitivity around a position where the first conductive element 210 is intersected with the second conductive element 220. It should be noted that, although shapes of the first connection pattern 214a and the secondary conductive pattern 222b are specifically proposed as above, the invention is not limited thereto. In other embodiments, the first connection pattern 214a may be a straight linear shape or a polygon, and the secondary conductive pattern 222b may be any shapes surrounded by a pattern of a normal projection of the first connection pattern 214a. Namely, profiles of the first connection pattern 214a and the secondary conductive pattern 222b are not particularly limited in the invention, and it falls in the scope of the invention for which protection is sought as long as the normal projection of the first connection pattern 214a is capable of surrounding the secondary conductive pattern 222b.

As shown in FIG. 2B, the width of the intersection portion 224a located on the insulation pattern 230 is represented as W1, in which it satisfies the condition of 100 μm<W1≦300 μm. In the present embodiment, the width W1 of the intersection portion 224a may be slightly larger than a linewidth of the first connection pattern 214a. Since the width W1 of the intersection portion 224a is well controlled, the intersection portion 224a has increased resistance to electrostatic discharge, such that the intersection portion 224a may not be completed fractured when it suffers damage from electrostatic discharge. In other words, the second conductive element 220 may be ensured to maintain its normal performance.

In some other embodiments not illustrated, layers of the first conductive element 210 and the second conductive element 220 depicted in FIG. 2A may be inverted. Namely, the conductive elements arranged along the first path P1 in FIG. 2A may be rearranged so as to be the second conductive element that partially covers the insulation pattern. Meanwhile, the conductive elements arranged along the first path P2 may be rearranged so as to be the first conductive element partially covered by the insulation pattern. In this case, the intersection portion of the second conductive element is of two arc-shaped patterns, and it is required that a linewidth of the two arc-shaped patterns satisfies a condition of being greater than 100 μm and less than or equal to 300 μm. The second conductive element has only the primary conductive pattern without having the secondary conductive pattern. The first connection pattern and the second connection pattern of the first conductive element are both of a circular shape, and the first connection pattern is surrounded by the normal projection of the intersection portions.

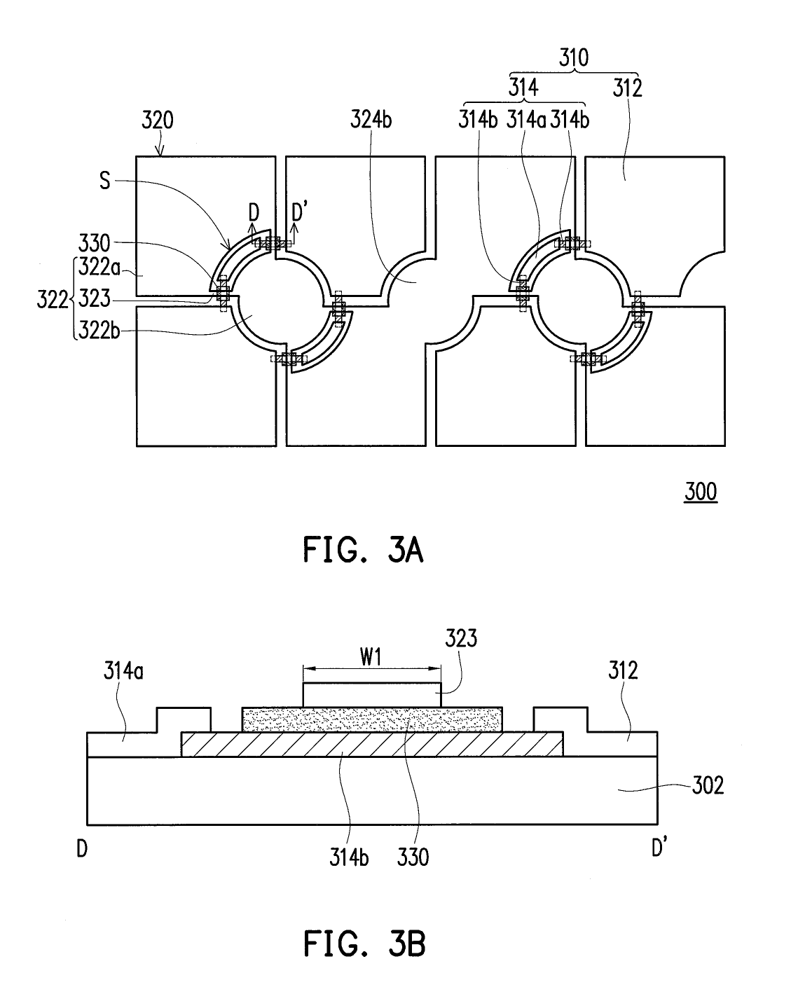

FIG. 3A is a schematic top view of a touch panel according to another embodiment of the invention. FIG. 3B is a schematic cross-sectional view taken along line D-D′ depicted in FIG. 3A. Referring to FIG. 3A and FIG. 3B together, a touch panel 300 is similar to the touch panel 200 of FIG. 2A, and a difference thereof is described below. The touch panel 300 includes a plurality of first conductive elements 310 and a plurality of second conductive elements 320 disposed on a substrate 302. The second conductive element 320 includes a plurality of second conductive patterns 322 and a plurality of second connection portions 324b, and adjacent ones of the second conductive patterns 322 can be electrically connected through one of the second connection portions 324b. The second conductive pattern 322 has two primary conductive patterns 322a, a secondary conductive pattern 322b, and a hollow portion S. Therein, the secondary conductive pattern 322b is disposed between the two primary conductive patterns 322a, and an area of the secondary conductive pattern 322b is less than an area of the primary conductive pattern 322a. In the present embodiment, the hollow portion S is located in the primary conductive pattern 322a, and intersection portions 323 are located at two ends of the hollow portion S. A first connection pattern 314 includes a filling section 314a and two first intersecting sections 314b. Therein, the filling section 314a is located in the hollow portion S; the first intersecting section 314b is intersected with the intersection portion 323; and the first intersecting section 314b is electrically connected to the filling section 314a and the first conductive pattern 312, as shown in FIG. 3B. By adopting a pattern design of the hollow portion S and the filling section 314a, the fringing capacitance of the first connection pattern 314 and the second conductive element 320 may be increased, so as to improve mutual induction sensitivity between the first conductive element 310 and the second conductive element 320. Specifically, similar to FIG. 1B, the filling section 314a and the first conductive pattern 312 may cover two ends of the first intersecting section 314b and extends to cover a part of the insulation pattern 330. According to this, it can make sure that the first intersecting section 314b can prevent damage from the etchant of subsequent patterning of the filling section 314a and the first conductive pattern 312. Therefore, it can make sure that the filling section 314a and the first conductive pattern 312 are electrically connected to the first intersecting section 314b.

In the present embodiment, the insulation pattern 330 covers on the first intersecting section 314b, and the intersection portion 323 is disposed on the insulation portion 330. Herein, a linewidth of the intersection portion 323 is represented as W1, in which it satisfies the condition of 100 μm<W1≦300 μm. Since the width of the intersection portion 323 is well controlled, the intersection portion 323 has increased resistance to electrostatic discharge, such that the intersection portion 323 may not be completed fractured when it suffers damage from electrostatic discharge. Therefore, the second conductive element 320 of the touch panel 300 may be ensured to maintain its normal performance. In addition, in comparison with the embodiment depicted in FIG. 2A, the present embodiment may effectively reduce an area of the insulation pattern 330, and reduce areas where the first connection patterns 314 and the second conductive elements 320 overlap, thereby reducing both the parasitic capacitance and visibility of the intersections of the first conductive elements 310 and the second conductive elements 320.

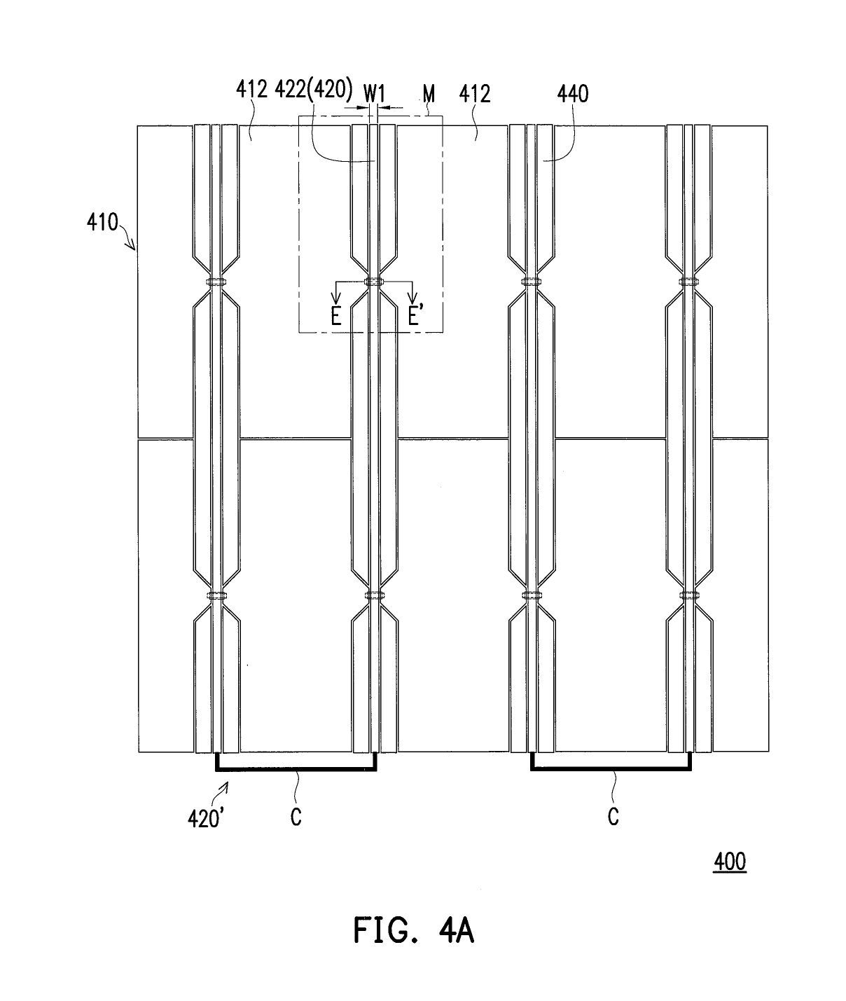

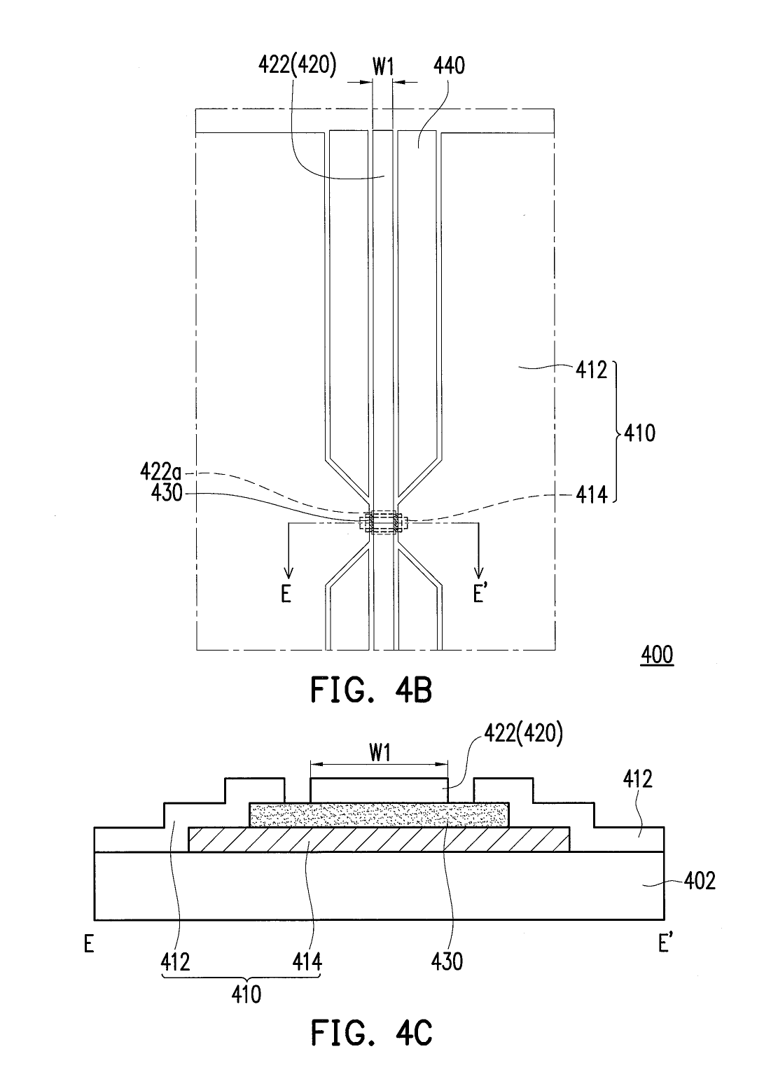

FIG. 4A is a schematic top view of a touch panel according to another embodiment of the invention. FIG. 4B is an enlarged schematic view of an area M depicted in FIG. 4A. FIG. 4C is a schematic cross-sectional view taken along line E-E′ depicted in FIG. 4A. Referring to FIG. 4A, FIG. 4B and FIG. 4C together, a touch panel 400 includes a plurality of first conductive elements 410 and a plurality of second conductive elements 420 disposed on a substrate 402. Herein, the signal transmission line is omitted in illustration, and the decoration layer may be selectively formed on the substrate 402. The first conductive elements 410 and the second conductive elements 420 are intersected with each other. The first conductive element 410 includes a plurality of first conductive patterns 412 and a plurality of first connection portions 414. Each of the first connection portions 414 is disposed between and electrically connects adjacent ones of the first conductive patterns 412 together.

The touch panel 400 further includes a plurality of insulation patterns 430. The insulation pattern 430 is disposed at the intersection of the first conductive element 410 and the second conductive element 420, so that the first conductive element 410 is electrically insulated from the second conductive element 420. More specifically, the insulation pattern 430 may be disposed on the first connection portion 414 without covering two ends of the first connection portion 414. The first conductive patterns 412 may cover the two ends of first connection portion 414 to be electrically connected to the first connection portion 414.

In the present embodiment, each second conductive element 420 includes a conductive trunk 422 having a plurality of intersection portions 422a intersected with the first connection portions 414. A linewidth of the conductive trunk 422 is uniform in all portions. Namely, a linewidth W1 of the intersection portion 422a is substantially identical to a linewidth of the conductive trunks 422, and the linewidth of the conductive trunks 422 can also be represented as W1 and satisfy the condition of 100 μm<W1≦300 μm. In consideration of deviation which may occur during actual fabrication, the linewidth W1 may allow a variation within ±5 μm yet still being substantially uniform. For instance, when the linewidth W1 is substantially 125 μm, the linewidth of the conductive trunk 422 may fall within a range of 120 to 130 μm, which is still of the linewidth being substantially uniform. Based on the structure disclosed in the present embodiment, all portions of the conductive trunk 422 have substantially identical linewidth, thus a layout of the second conductive elements 420 may be simpler, and the current crowding effect caused by intensive variations of the linewidth may be reduced.

Furthermore, since the conductive trunk 422 has the proper linewidth W1 to cross over the insulation patterns 430, the intersection portions 422a has increased resistance to electrostatic discharge, such that the conductive trunk 422 may not be completed fractured when it suffers damage from electrostatic discharge. Therefore, the second conductive elements 420 of the touch panel 400 may be ensured to maintain its normal performance. In the present embodiment, the conductive trunk 422 is a straight linear pattern. However, in other embodiments, the conductive trunk 422 may also be an irregular linear pattern, and it falls in the scope of the invention for which protection is sought as long as all portions of the conductive trunk 422 have the substantially identical linewidth W1 and in the range of 100 μm<W1≦300 μm. In addition, in the light shielding region, every two of the second conductive elements 420 are electrically connected together through a wire C to constitute a plurality of second conductive groups 420′ electrically independent from each other, so as to reduce the conduction impedance of the second conductive elements 420. A number of the second conductive elements 420 to be electrically connected together is not particularly limited in the invention. In other embodiments, each second conductive group 420′ may also be composed of three or more of the second conductive elements 420 parallel connected by the wire C. In addition, in other embodiments, the second conductive elements 420 in the second conductive group 420′ may also be driven separately to improve a touch resolution of the touch panel 400.

In addition, the touch panel 400 may further include a plurality of floating dummy electrodes 440 made of a conductive material. The floating dummy electrode 440 is located between the conductive trunk 422 and the first conductive pattern 412, so as to improve visual effects while reducing a RC loading. In the present embodiment, the floating dummy electrode 440 may has at least one terminal with acute angle. Accordingly, the RC loading may be further reduced to accelerate a charging/discharging speed for loading, so that the touch panel 400 may be suitable applied in high-resolution or large-size touch panels. In a more preferable embodiment, an insulating spacing between one of the conductive trunks 422 and one of the first conductive patterns 412 is full of two of the floating dummy electrodes 422. In comparison with an embodiment without using the floating dummy electrodes 440 (i.e., there is no floating dummy electrode 422 disposed at the insulating spacing between the conductive trunk 422 and the first conductive pattern 412), when the insulating spacing becomes relatively smaller, a capacitance between the conductive trunk 422 and the first conductive pattern 412 becomes relatively greater, while a value of the RC loading also becomes relatively greater; and when the insulating spacing becomes relatively greater, although the RC loading may be reduced, but the first conductive elements 410 and the second conductive elements 420 may prone to be seen.

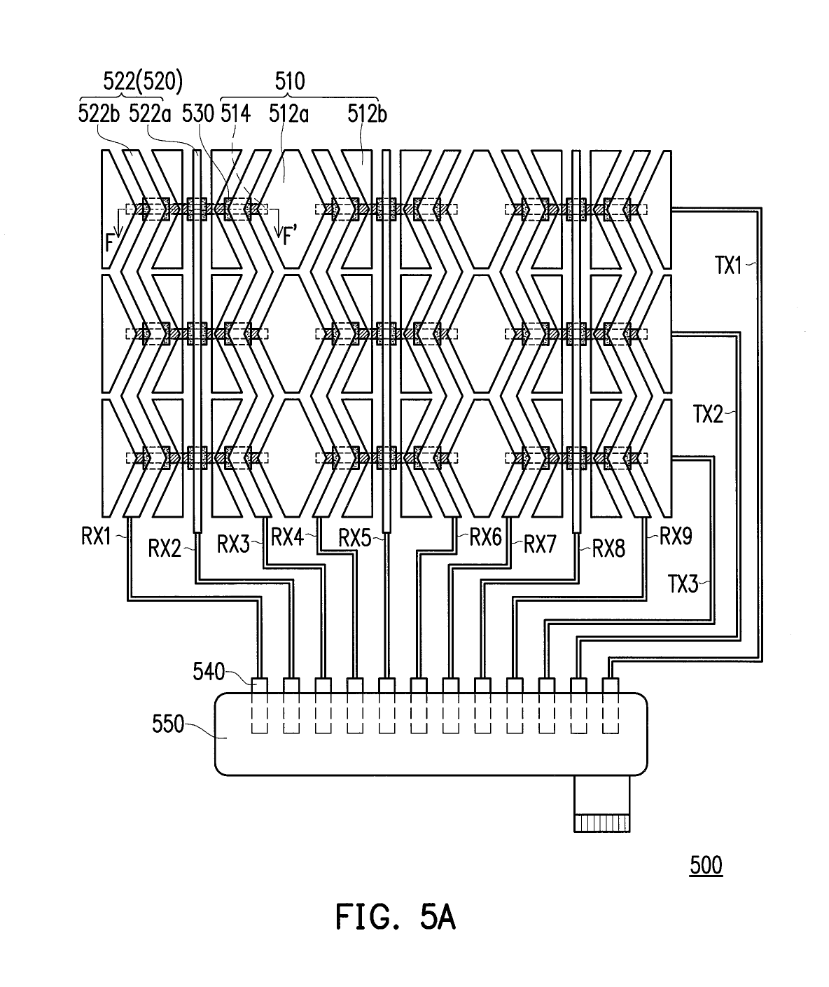

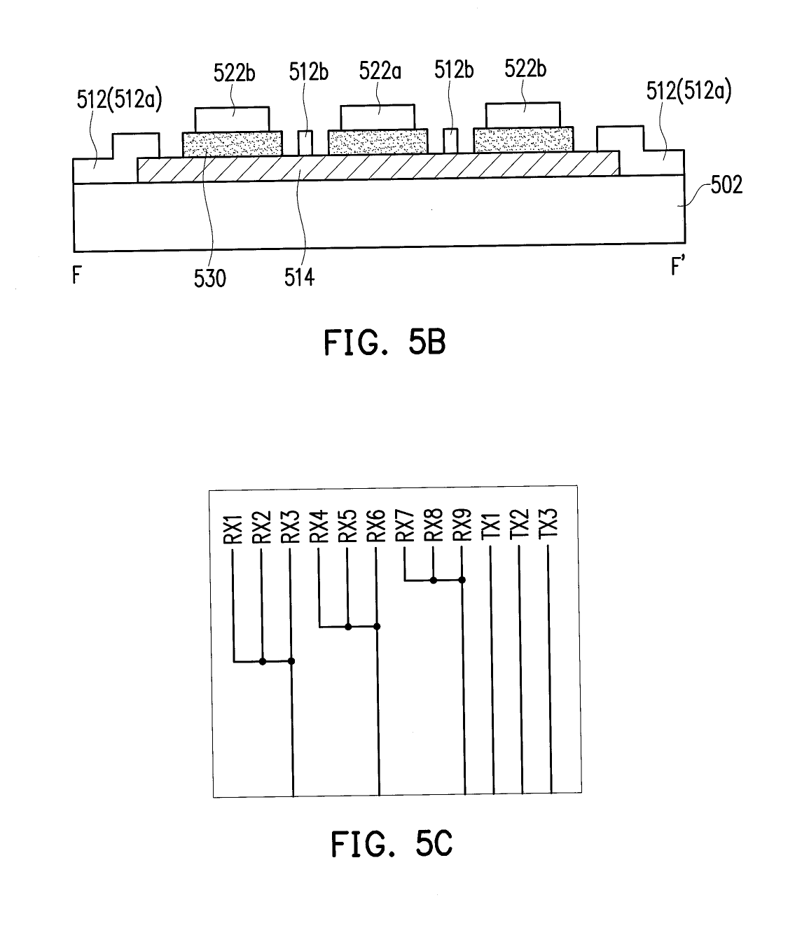

FIG. 5A is a schematic top view of a touch panel according to another embodiment of the invention. FIG. 5B is a schematic cross-sectional view taken along line F-F′ depicted in FIG. 5A. Referring to FIG. 5A and FIG. 5B, a touch panel 500 includes a plurality of first conductive elements 510 and a plurality of second conductive elements 520 disposed on a substrate 502. The touch panel 500 is similar to the touch panel 400 depicted in FIG. 4A, a difference between the two is that, in the touch panel 500, the first conductive element 510 has two types of first conductive patterns 512; and the second conductive elements 520 have two types of conductive trunks 522. The conductive trunks 522 include first linear patterns 522a and second linear patterns 522b. The first linear pattern 522a may be a straight linear pattern, and the second linear pattern 522b may be a zigzag linear pattern. Therein, taking one of the first linear patterns 522a as a basis, the second linear patterns 522b located at two opposite sides of the first linear pattern 522a are disposed in a mirror-image relation. Namely, a repeating unit can be composed of three of the conductive trunks 522 including one of the first linear patterns 522a and two of the second linear patterns 522b. In the present embodiment, the first linear pattern 522a and the second linear pattern 522b have uniform linewidths, respectively, and said linewidths are greater than 100 μm and less than or equal to 300 μm. The linewidth of the first linear pattern 522a may be identical to or different from the linewidth of the second linear pattern 522b. The first conductive patterns 512 of the first conductive element 510 include first sub-patterns 512a and second sub-patterns 512b. The first sub-patterns 512a are disposed between adjacent two of the second linear patterns 522b, and the second sub-patterns 512b are disposed between the first linear pattern 522a and the second linear pattern 522b. The first sub-pattern 512a is electrically connected to the second sub-pattern 512b through a first connection portion 514. A plurality of insulation patterns 530 are respectively disposed at the intersections of the first conductive elements 510 and the second conductive elements 520 so as to separate the first conductive elements 510 and the second conductive elements 520.

In the present embodiment, each of the conductive trunks 522 of the second conductive elements 522 is connected to a corresponding one of bonding pads 540 through, for example, one of signal transmission lines RX1 to RX9 located in the light shielding region, and each of the first conductive elements 510 is connected to a corresponding one of bonding pads 540 through, for example, one of signal transmission lines TX1 to TX3 located in the light shielding region. The bonding pads 540 are conducted to pins of a flexible printed circuit board 550, and a control circuit (not illustrated) may be disposed on the flexible printed circuit board 550 to transmit or receive signals. For instance, the control circuit may transmit driving signals to the signal transmission lines TX1 to TX3, and receive signals from the signal transmission lines RX1 to RX9, but the invention is not limited thereto.

FIG. 5C is a schematic view for electrical connection of the control circuit of the present embodiment. Referring to FIGS. 5A and 5C, the control circuit of the present embodiment may automatically switch a touch mode between a low resolution and a high resolution based on a type of a touch event (e.g., touched by the finger or touched by the stylus). For instance, when the touch panel 500 is touched by the stylus, the control circuit adopts the high resolution touch mode. In this case, the signals from the signal transmission lines RX1 to RX9 are respectively and independently received by the control circuit, so that the touch panel 500 has a resolution of 3×9. When the touch panel 500 is touched by the finger, the control circuit adopts the low resolution touch mode. In this case, the signals from every three adjacent signal transmission lines (RX1 to RX3, RX4 to EX6 and RX7 to RX9) may be simultaneously received by the control circuit, so that the touch panel 500 has a resolution of 3×3. Accordingly, a consumed power of the touch panel 500 may be effectively saved by switching to the low resolution touch mode.

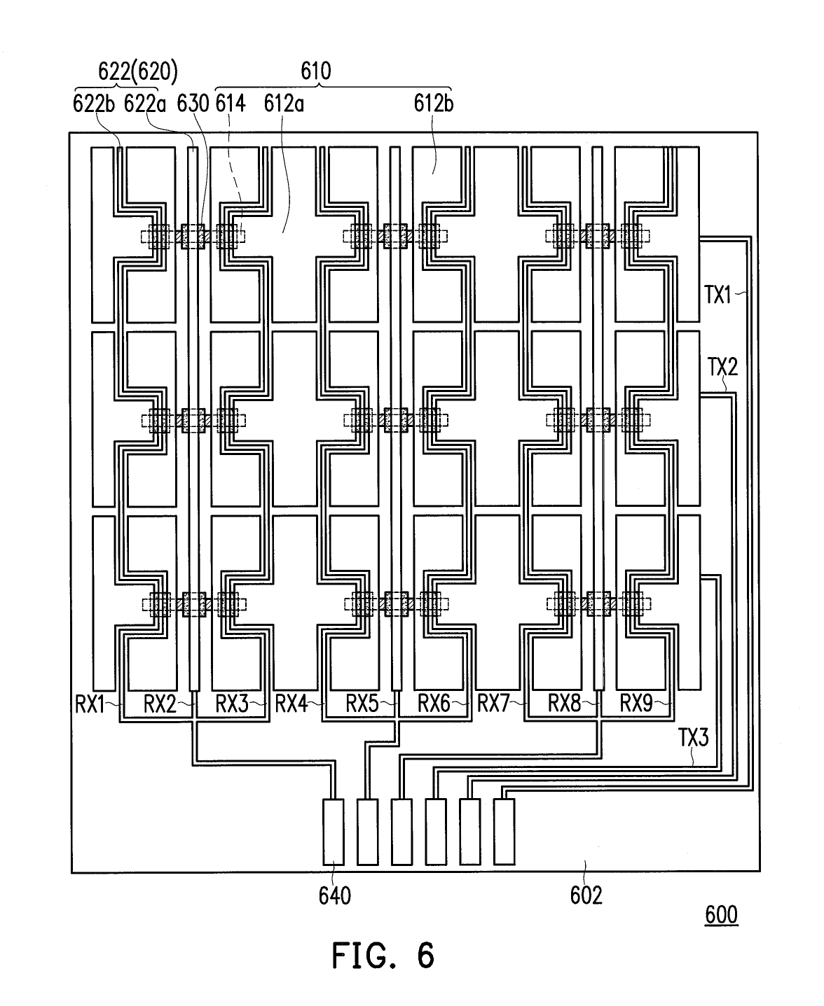

FIG. 6 is a schematic top view of a touch panel according to another embodiment of the invention. Referring to FIG. 6, a touch panel 600 is similar to the touch panel 500 depicted in FIG. 5A, a difference between the two is that, every three of the signal transmission lines (e.g., RX1 to RX3, RX4 to EX6 and RX7 to RX9) connected to second conductive elements 620 are connected into a bundle on a substrate 602 and electrically connected to a corresponding one of bonding pads 640. Conductive trunks 622 of the present embodiment include first linear patterns 622a and second linear patterns 622b. The first linear pattern 622a may be a straight linear pattern, and the second linear pattern 622b may be a right angle multi-bending linear pattern. A length of the second linear pattern 622b may be greater than a length of the first linear pattern 622a. For decreasing the impedance differences between the second linear pattern 622b and the first linear pattern 622a, optionally, a linewidth of the second linear pattern 622b may be less than a linewidth of the first linear pattern 622a. Therein, taking one of the first linear patterns 622a as a basis, the second linear patterns 622b located at two opposite sides of the first linear pattern 622a are disposed in a mirror-image relation. In the present embodiment, the first conductive patterns 612 of the first conductive element 610 include first sub-patterns 612a and second sub-patterns 612b. The first sub-patterns 612a are disposed between adjacent two of the second linear patterns 622b, and the second sub-patterns 612b are disposed between the first linear pattern 622a and the second linear pattern 622b. The first sub-pattern 612a is electrically connected to the second sub-pattern 612b through a first connection portion 614. A plurality of insulation patterns 630 are respectively disposed at regions where the first conductive elements 610 and the second conductive element 620 are intersected with other so as to separate the first conductive elements 610 and the second conductive elements 620.

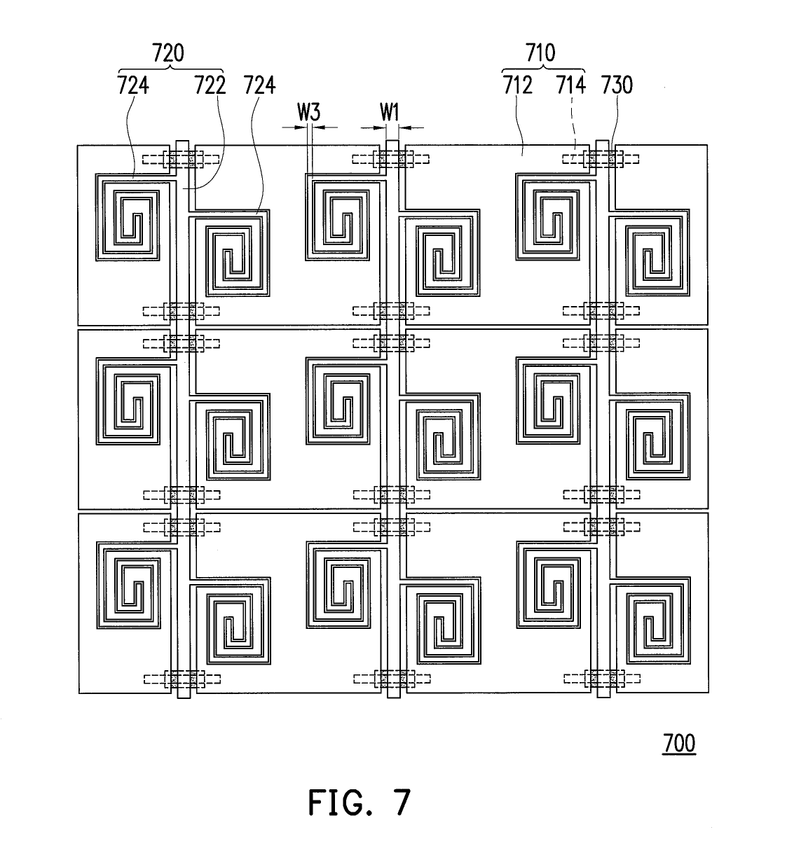

FIG. 7 is a schematic top view of a touch panel according to another embodiment of the invention. Referring to FIG. 7, a touch panel 700 is similar to the touch panel 400, a difference between the two is that, each second conductive element 720 of the touch panel 700 further includes a plurality of second conductive branches 724. The second conductive branches 724 are extruded from two opposite sides of a conductive trunk 722, and surrounded by the first conductive pattern 712 of the first conductive element 710. The adjacent first conductive patterns 712 are electrically connected to each other through a first connection portion 714. From another perspective, the first conductive pattern 712 includes an opening having a special arrangement design, and the second conductive branch 724 is, for example, disposed in the opening of the first conductive pattern 712. An arrangement of the second conductive branch 724 is complementary to a profile of the opening of the first conductive pattern 712. As shown in FIG. 7, the second conductive branch 724 is arranged in a rectangular spiral shape, such that the opening of the first conductive pattern 712 is arranged in a corresponding rectangular spiral shape suitable for accommodating the second conductive branch 724. By adopting the second conductive branches 724, the touch panel 700 may provide a favorable sensing sensitivity and linearity. Of course, shapes for the arrangements of the first conductive pattern 712 and the second conductive branches 724 are not particularly limited in the invention as long as the shapes for the arrangements of the two are complementary. In order to accomplish the purpose of the invention, a linewidth W1 of the conductive trunk 722 is greater than 100 μm and less than or equal to 300 μm. Furthermore, the second conductive branches 724 can also have a uniform linewidth W3, in which the linewidth W3 can be not greater than the linewidth W1 of the conductive trunk 722.

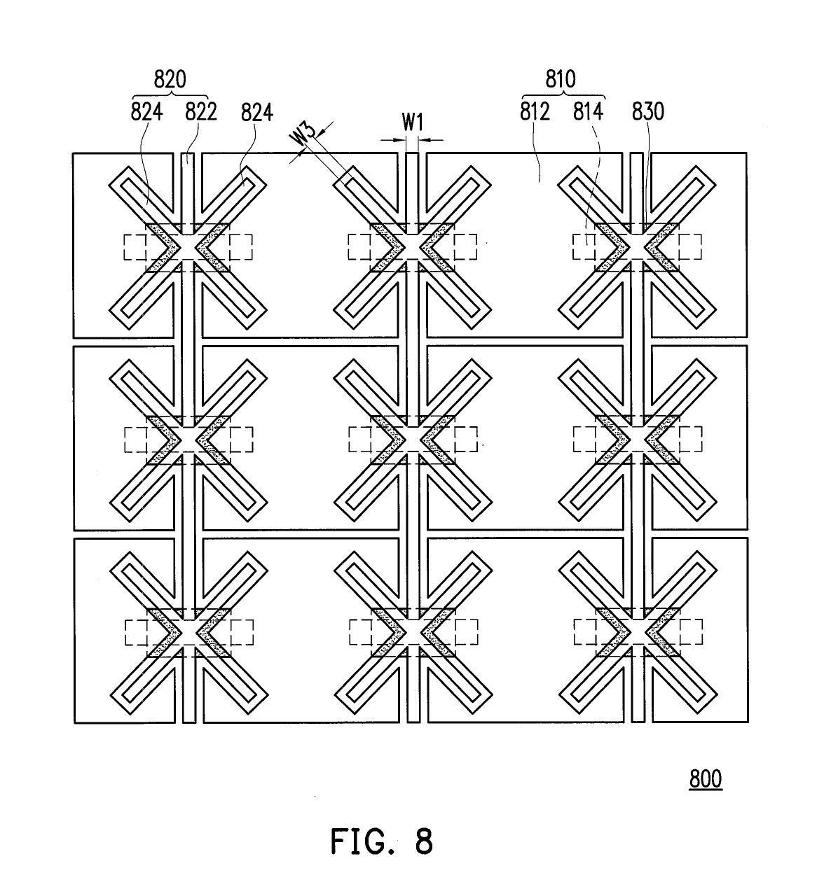

FIG. 8 is a schematic top view of a touch panel according to another embodiment of the invention. Referring to FIG. 8, a touch panel 800 is similar to the touch panel 700, a difference between the two is that, a second conductive element 820 of the touch panel 800 includes a plurality of second conductive branches 824, and the second conductive branches 824 are of, for example, a straight linear shape. Each of the second conductive branches 824 is outwardly extruded from a conductive trunk 822 and inwardly extended into notches of the first conductive pattern 812 of the first conductive element 810. The adjacent first conductive patterns 812 are electrically connected to each other through a first connection portion 814. An extending direction of the second conductive branch 824 is not parallel to an extending direction of the conductive trunk 822. As similar to that in the foregoing embodiments, by adopting the second conductive branches 824, the touch panel 800 may provide a favorable sensing sensitivity and linearity.

In summary, in the touch panel according to the embodiments of the invention, the linewidth of the second conductive element located on the insulation pattern is controlled to fall within an appropriate range, so that the second conductive element is not easily broken even if the second conductive element on the insulation pattern suffers damage from the electrostatic discharge, thereby ensuring that the touch panel may provide a favorable performance. In addition, in the touch panel according to one of the embodiments of the invention, the second conductive element may have a conductive trunk with a uniform linewidth, so that the current crowding effect may be reduced, and fabrication may be easier by a simpler arrangement.

What is claimed is:

1. A touch panel, comprising:
a substrate;
a plurality of first conductive elements disposed on the substrate, each of the first conductive elements including a plurality of first conductive patterns and a plurality of first connection portions, each of the first connection portions being disposed between adjacent two of the first conductive patterns, and each of the first conductive patterns being electrically connected to one of the first connection portions; and
a plurality of second conductive elements, being electrically insulated from the first conductive elements, wherein each of the second conductive elements includes a plurality of intersection portions respectively intersected with the first connection portions, and a linewidth of the intersection portion is W1, and satisfying a condition of:
100 μm<W1≦300 μm;
wherein a sum of areas of regions where the first conductive elements and the second conductive elements are not overlapped is greater than a sum of areas of regions where the first conductive elements and the second conductive elements are overlapped.

2. The touch panel as claimed in claim 1, further comprising a plurality of insulation patterns, and each of the insulation patterns being disposed between one of the first connection portions and a corresponding one of the intersection portions intersected with the one of the first connection portions.

3. The touch panel as claimed in any one of claim 1, wherein each of the second conductive elements includes a plurality of second conductive patterns and at least one second connection portion, each of the at least one second connection portion is disposed between adjacent two of the second conductive patterns, each of the second conductive patterns is electrically connected to one of the at least one second connection portion, and the intersection portions are located in the second conductive patterns.

4. The touch panel as claimed in claim 3, wherein a linewidth of the second connection portion is W2, and satisfies a condition of 20 μm<W2<W1.

5. The touch panel as claimed in claim 4, wherein an accommodating space is defined between adjacent two of the second conductive patterns and any one of two sides of the second connection portion, and each of the first conductive elements has at least one first conductive branch being extended into the accommodating space.

6. The touch panel as claimed in claim 2, wherein the insulation pattern exposes two ends of the first connection portion, the first conductive patterns are disposed on the two ends of the first connection portion, a partial region of the insulation pattern and the substrate, the first conductive pattern being inwardly extended from an edge of the insulation pattern for a distance not less than 20 μm.

7. The touch panel as claimed in claim 1, wherein a minimum linewidth of the first connection portion is not greater than the linewidth of the intersection portion.

8. The touch panel as claimed in claim 1, wherein the first connection portions include a plurality of first connection patterns and a plurality of second connection patterns, and the first connection patterns and the second connection patterns are alternately disposed between adjacent two of the first conductive patterns, wherein two or more of the first connection patterns are disposed between adjacent two of part of the first conductive patterns, and each two of the first connection patterns encircle an opening.

9. The touch panel as claimed in claim 8, wherein a width of the second connection pattern is greater than a width of the first connection pattern.

10. The touch panel as claimed in claim 8, wherein a part of the second conductive element is surrounded by a normal projection of two of the first connection patterns being arc-shaped.

11. The touch panel as claimed in claim 8, wherein the first connection pattern is surrounded by a normal projection of two of the intersection portions being arc-shaped.

12. The touch panel as claimed in claim 8, wherein a maximum width of the second connection pattern is greater than a minimum width of the first conductive pattern.

13. The touch panel as claimed in claim 1, wherein the second conductive element includes a hollow portion, the intersection portions are located at two ends of the hollow portion, the first connection portion includes a filling section and a plurality of first intersecting sections, the filling section is located in the hollow portion, the first intersecting sections are located at the two ends of the filling section, and each of the first intersecting sections is intersected with one of the intersection portions and electrically connects the filling section and one of the first conductive patterns together.

14. The touch panel as claimed in any of claim 1, wherein each of the second conductive elements includes a conductive trunk, and the intersection portions are located in the conductive trunk, wherein a linewidth of any portion of the conductive trunk other than the intersection portions is substantially identical to a linewidth of any one of the intersection portions.

15. The touch panel as claimed in claim 14, wherein each of the second conductive elements further includes a plurality of second conductive branches, and the second conductive branches are extruded from two opposite sides of the conductive trunk.

16. The touch panel as claimed in claim 15, wherein a linewidth W3 of each of the second branches is substantially uniform, and is not greater than the linewidth W1.

17. The touch panel as claimed in claim 14, further comprising a plurality of floating dummy electrodes respectively located between the conductive trunk and the first conductive pattern, wherein each of the floating dummy electrodes has at least one terminal with acute angle.

18. The touch panel as claimed in claim 14, further comprising a plurality of floating dummy electrodes, wherein two or more of the floating dummy electrodes are located an insulating spacing between one of the conductive trunks and the adjacent one of the first conductive patterns.

19. A touch panel having a light transmissive region, comprising:
a substrate made of a light transmissive material;
a plurality of first conductive elements disposed on the substrate and at least located at the light transmissive region, each of the first conductive elements including a plurality of first conductive patterns and a plurality of first connection portions, each of the first connection portions being disposed between adjacent two of the first conductive patterns, and each of the first conductive patterns and one of the first connection portions being electrically connected to each other;
a plurality of second conductive elements disposed on the substrate and at least located at the light transmissive region, the first conductive elements and the second conductive elements are intersected with each other and electrically insulated, wherein each of the second conductive elements includes a plurality of intersection portions respectively intersected with the first connection portions of each of the first conductive elements, and a linewidth of the intersection portion is greater than a linewidth of the first connection portion; and
a plurality of insulation patterns, each of the insulation patterns being disposed between one of the first connection portions and a corresponding one of the intersection portions intersected with the one of the first connection portions;
wherein a sum of areas of regions where the first conductive elements and the second conductive elements are not overlapped is greater than a sum of areas of regions where the first conductive elements and the second conductive elements are overlapped.

20. The touch panel as claimed in claim 19, wherein a linewidth of the intersection portion is W1, and satisfies a condition of 100 μm<W1≦300 μm.

21. The touch panel as claimed in claim 19, wherein each of the second conductive elements includes a conductive trunk, and the intersection portions are located in the conductive trunk, wherein a linewidth of any portion of the conductive trunk other than the intersection portions is substantially identical to a linewidth of any one of the intersection portions.

22. The touch panel as claimed in claim 19, further comprising a decoration layer and a plurality of signal transmission lines, the decoration layer being disposed on the substrate and corresponding to a light shielding region adjoined to the light transmissive region, the signal transmission lines being concealed by the decoration layer, wherein the first conductive elements and the second conductive elements are further located at the light shielding region to electrically connect to the signal transmission lines on the decoration layer.
